(19) United States
(12) Patent Application Publication
(10) Pub. No.: US 2013/0235357 A1
(43) Pub. Date: Sep. 12, 2013

(54) System and Method for Particle Control Near A Reticle

(71) Applicant: KLA-TENCOR CORPORATION, Milpitas, CA (US)

(72) Inventors: Gildardo Delgado, Livermore, CA (US); Frank Chilese, San Ramon, CA (US)

(73) Assignee: KLA-TENCOR CORPORATION, Milpitas, CA (US)

(21) Appl. No.: 13/790,764

(22) Filed: Mar. 8, 2013

Related U.S. Application Data
(60) Provisional application No. 61/609,640, filed on Mar. 12, 2012.

(51) Int. Cl. G03F 7/20

(52) U.S. Cl. CPC G03F 7/70908
USPC 355/30; 355/77

(57) ABSTRACT

Controlling particles near a reticle of a lithography or reticle inspection system may include generating a curtain of ultraviolet light about a reticle protection area of a reticle by illuminating a region surrounding the reticle protection area with ultraviolet light having sufficient energy to induce a charge on one or more particles traversing the curtain of ultraviolet light, generating an electric field in a region positioned between the generated curtain of ultraviolet light and the reticle protection area, the electric field generated between a first charging element and a second charging element having an opposite charge to the first charging element, directing one or more charged particles to the first charging element or the second charging element using the generated electric field; and capturing the one or more charged particles on the first charging element or the second charging element.

### CROSS-REFERENCE TO RELATED APPLICATION

The present application is related to and claims the benefit of the earliest available effective filing date(s) from the following listed application(s) (the “Related applications”) (e.g., claims earliest available priority dates for other than provisional patent applications or claims benefits under 35 USC §119(e) for provisional patent applications, for any and all parent, grandparent, great-grandparent, etc. applications of the Related application(s)).

### RELATED APPLICATIONS

For purposes of the USPTO extra-statutory requirements, the present application constitutes a regular (non-provisional) patent application of United States Provisional Patent Application entitled PARTICLE CONTROL NEAR RETICLE USING UV LIGHT CURTAIN, naming Gildardo Delgado and Frank Chilese as inventors, filed Mar. 12, 2012, Application Ser. No. 61/609,640.

### TECHNICAL FIELD

The present invention generally relates to the control of particles in the vicinity of a reticle mounted on a reticle stage of a lithography tool, including a reticle inspection tool or a wafer processing tool.

### BACKGROUND

The continued shrinking of design geometries in integrated circuit devices generates a continual need for improved optical inspection tools. For example, light sources for photolithography systems have historically evolved to smaller and smaller wavelengths, thereby allowing the construction of smaller and smaller structures. For instance, the use of visible wavelength light (e.g., 400 nm) gave way to near ultraviolet light (e.g., 300 nm), which then gave way to deep ultraviolet (DUV) light (e.g., 200 nm). Then, more recently, DUV light based sources have given way to extreme ultraviolet (EUV) sources (e.g., 13.5 nm).

Generally, particles scatter less energy than larger defects and, therefore, tend to be more difficult to detect using longer wavelength radiation. As such, light sources and systems capable of utilizing smaller wavelengths and increased illumination energy are more effective at locating particles. This allows particles to be detected or identified by class, based on shape, location, device effect and the like, in an automated fashion. This also allows for detected troublesome defects to be distinguished from “nuisance defects.”

One disadvantage of inspection tools operating in the EUV regime is that a particle protection device, such as a pellicle, which is commonly used in tools at longer wavelengths, cannot be used in EUV settings because the protection device is opaque at EUV wavelengths. Further, the critical dimensions of the reticles intended to be inspected on a EUV tool may be so small that nearly any particle present on the reticle surface will cause unacceptable problems. Several particle protection mechanisms have been proposed, studied or used to protect the reticle from particles. By way of example, the contaminant particles may commonly emanate from nearby optics used to direct inspection light to the reticle, which is generally directed to the reticle via a central hole in a nearby plate. In addition, the reticle stage used to move the reticle during inspection may also be a source of contaminant particles, which may come into contact with the reticle around the circumference of the reticle, rather than near the center of the reticle.

Presently, particle control in light-based reticle inspection system is carried out with flowing air, which pushes the particles in a known direction. In vacuum systems, such as in e-beam inspect systems, particle control is done with slight amounts of positive pressure and particle reduction methods designed to reduce the number of particles in general. The prior methods have several advantages. For example, they have not shown capable of eliminating particles down to 10 nm in diameter. In addition, prior art methods have only been used in processes that allow reticle cleaning after inspection. However, the EUV reticle inspection tool must contend with smaller particles since no cleaning is allowed after inspection. Therefore, it would be desirable to provide a system and method that cures the defects of the prior art, providing for improved contaminant particle control and capture for reticle inspection tools and lithography tools operating in the EUV regime.

### SUMMARY

An apparatus for particle control near a reticle of a lithography tool is disclosed. In a first aspect, the apparatus may include, but is not limited to, a curtain generation unit configured to generate a curtain of ultraviolet light about a reticle protection area surrounding a reticle by directing ultraviolet light to a selected region about the reticle protection area, the ultraviolet light having sufficient energy to induce a charge on one or more particles traversing the curtain of ultraviolet light; and an electric field generation unit configured to generate an electric field spanning a region positioned between the curtain of ultraviolet light and the reticle protection area.

In another aspect, the apparatus may include, but is not limited to, a curtain generation unit configured to generate a curtain of ultraviolet light about a reticle protection area surrounding a reticle by directing ultraviolet light to a selected region about the reticle protection area, the ultraviolet light having sufficient energy to induce a charge on one or more particles traversing the curtain of ultraviolet light; a thermophoretic plate arranged near a surface of the reticle and suitable for directing one or more particles away from the reticle protection area about the reticle via the thermophoretic effect; and an electric field generation unit configured to generate an electric field spanning a region positioned between the curtain of ultraviolet light and the reticle protection area, wherein the electric field generation unit is configured to charge the thermophoretic plate and charge a second charging element, wherein the thermophoretic plate and the second charging element have opposite polarity.

In another aspect, the apparatus may include, but is not limited to, a curtain generation unit configured to generate a curtain of ultraviolet light about a critical region of an extreme ultraviolet light optical tool by directing ultraviolet light to a selected region about the critical region, the ultraviolet light having sufficient energy to induce a charge on one or more particles traversing the curtain of ultraviolet light; and an electric field generation unit configured to generate an electric field spanning a region positioned between the curtain of ultraviolet light and the critical region.

A method for particle control near a reticle of a lithography tool is disclosed. In a first aspect, the method may include, but is not limited to, generating a curtain of ultraviolet light about a reticle protection area of a reticle by illuminating a region surrounding the reticle protection area with ultraviolet light having sufficient energy to induce a charge on one or more particles traversing the curtain of ultraviolet light; generating an electric field in a region positioned between the generated curtain of ultraviolet light and the reticle protection area, the electric field generated between a first charging element and a second charging element having an opposite charge to the first charging element; directing one or more charged particles to the first charging element or the second charging element using the generated electric field; and capturing the one or more charged particles on the first charging element or the second charging element.

In another aspect, the method may include, but is not limited to, generating a curtain of ultraviolet light about a critical region of an extreme ultraviolet optical tool by illuminating a region surrounding the critical region with ultraviolet light having sufficient energy to induce a charge on one or more particles traversing the curtain of ultraviolet light; generating an electric field in a region positioned between the generated curtain of ultraviolet light and the critical region, the electric field generated between a first charging element and a second charging element having an opposite charge to the first charging element; directing one or more charged particles to the first charging element or the second charging element using the generated electric field; and capturing the one or more charged particles on the first charging element or the second charging element.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the disclosure may be better understood by those skilled in the art by reference to the accompanying figures in which:

FIG. 1A is a schematic view of system for controlling particles near a reticle, in accordance with one embodiment of the present invention.

FIG. 1B is a schematic view of a voltage source of an electric field generation unit of the system for controlling particles near a reticle, in accordance with one embodiment of the present invention.

FIG. 1C is a schematic view of an annular metal plate of an electric field generation unit of the system for controlling particles near a reticle, in accordance with one embodiment of the present invention.

FIG. 2A is a schematic view of system for controlling particles near a reticle, in accordance with one embodiment of the present invention.

FIG. 2B is a schematic view of system for controlling particles near a reticle, in accordance with one embodiment of the present invention.

FIG. 3 is a process flow diagram depicting a method for controlling particles near a reticle, in accordance with one embodiment of the present invention

FIG. 4 is a process flow diagram depicting a method for controlling particles near a critical region of an extreme ultraviolet optical tool, in accordance with one embodiment of the present invention.

### DETAILED DESCRIPTION OF THE INVENTION

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention. Reference will now be made in detail to the subject matter disclosed, which is illustrated in the accompanying drawings.

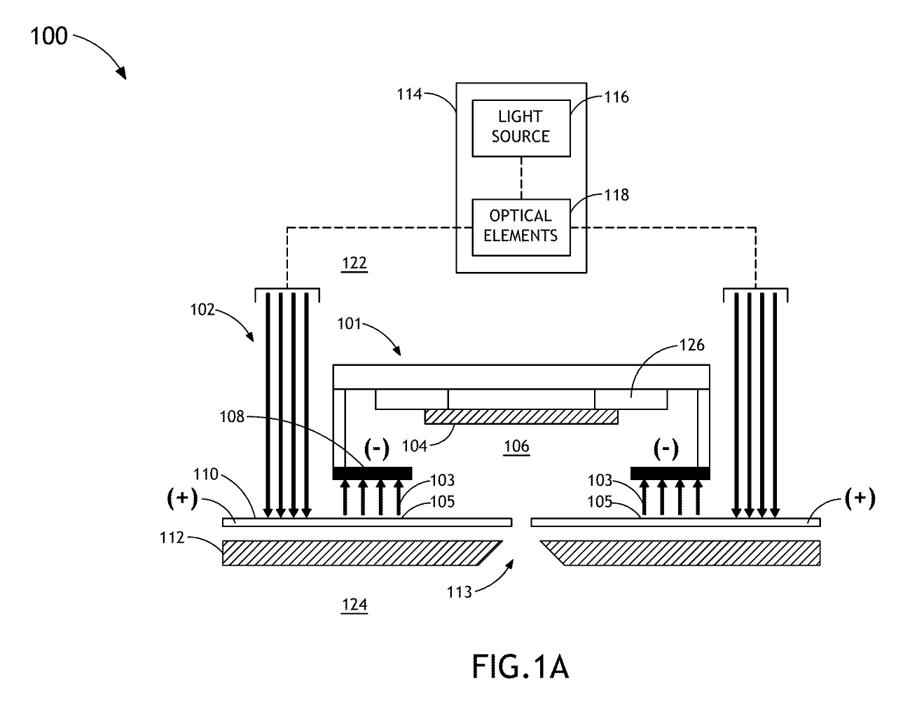

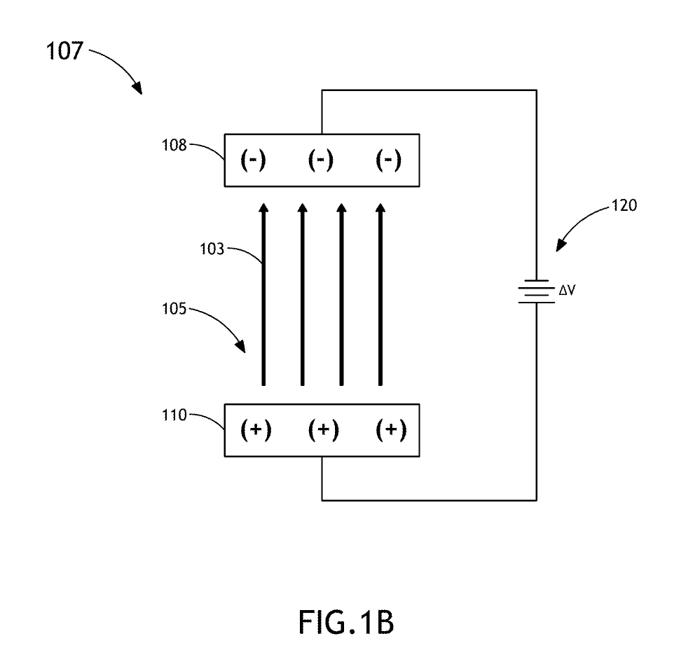

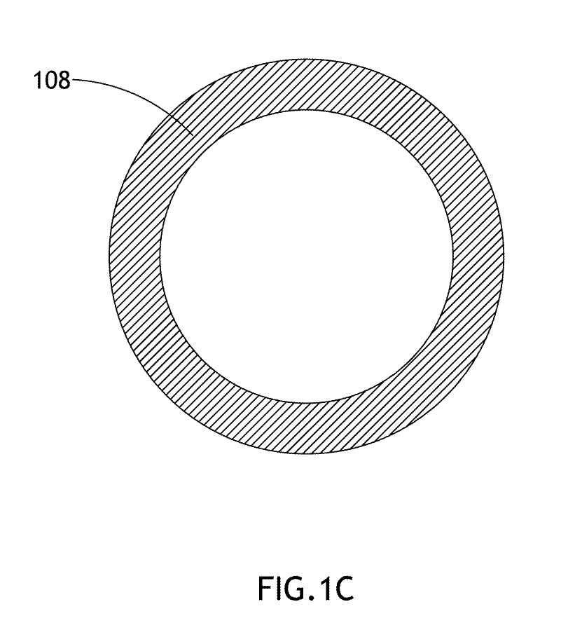

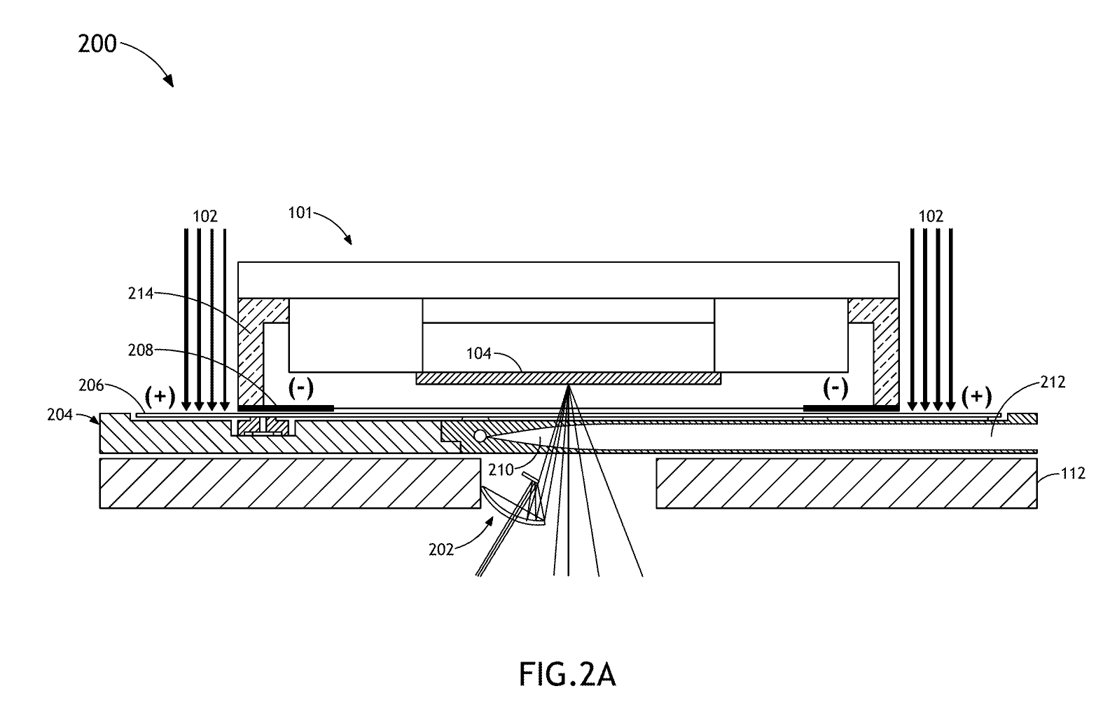

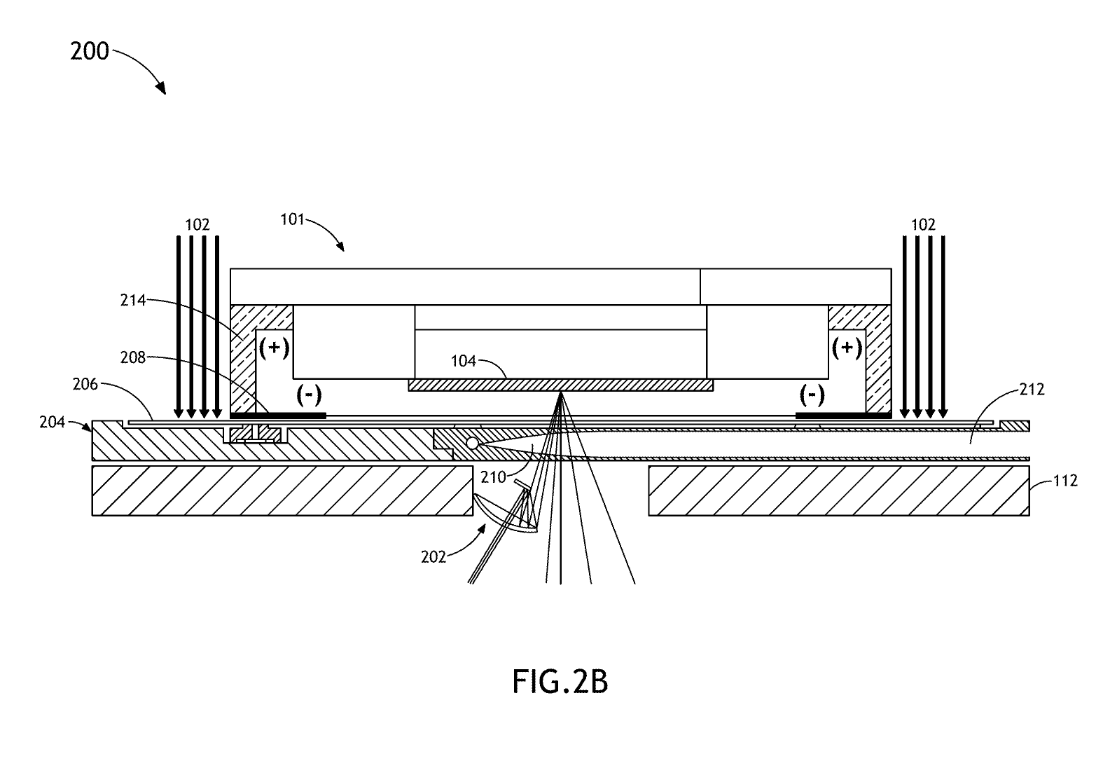

Referring generally to FIGS. 1A through 2B, a system 100 for particle control near a reticle is described in accordance with the present disclosure. The present invention is directed to a method and system for controlling particles (e.g., contaminant particles) near a reticle of a lithography system, such as an EUV lithography system. Embodiments of the present invention are suitable for generating a curtain of ultraviolet (UV) light about the moving portion of a reticle stage of a lithography system. The curtain (e.g., annular curtain) of ultraviolet light acts to illuminate particles traveling toward the reticle protection area of the reticle with UV light. The illumination of particles with UV light acts to induce a positive charge on the particles by stripping one or more free electrons from the particles. In turn, the present invention is further suitable for directing and/or capturing the particles charged by UV light exposure from the UV curtain using an electric field generated between a pair of oppositely charged plates. The charged plates and voltage control are configured to establish an electric field “zone” (e.g., annular zone) that extends across a region positioned between the UV light curtain and the reticle protection area of the reticle. The large generated electric field (e.g., 1-100 Volts/mm) provides a large force on the charged particles, which in turn acts to direct the charged particles along the electric field to one of the charged plates, thereby stopping the captured charged particles from reaching the reticle of the lithography system. In this regard, the light curtain and electric field zone of the present invention serve as a charged particle trap, thereby isolating the reticle protection area about the reticle from particles originating external to the reticle protection area.

FIGS. 1A and 1B illustrate a high level schematic view of a system 100 for particle control near a reticle, in accordance with the present invention. In one aspect of the present invention, the system 100 includes a light curtain generation unit 114 configured to generate a curtain of ultraviolet (UV) light 102 about a reticle protection area 106 surrounding a reticle 104 (e.g., reticle of lithography system) by directing ultraviolet light 102 to a selected region 105 about the reticle protection area 106. In one embodiment, the reticle 104 of the system 100 includes a reticle of a lithography system. For example, the reticle 104 of the system 100 may include a reticle of a EUV lithography system.

In another aspect of the present invention, the UV light utilized to form the curtain of UV light 102 has sufficient energy to induce a charge on one or more particles (e.g., contaminant particles) traversing the curtain of UV light 102.

In another aspect of the present invention, the system 100 includes an electric field generation unit 107 configured to generate an electric field 103 in a zone 105 between the curtain of UV light 102 and the reticle protection area 106 surrounding the reticle 104. In this regard, the electric field 103 extending across zone 105 may be used to direct and capture particles charged by the UV light curtain 102, thereby aiding in reducing the number of particles entering the reticle protection area 106 surrounding the reticle 104. In the case of particles positively charged by the UV light curtain, the particles will be directed toward the negatively charged element (e.g., charged plate). In cases where the initial state of the particles includes a sufficient negative charge level to disallow the positive charging via the UV light curtain, the electric field may still act to direct and capture the charged particles to the positively charged element (e.g., charged plate). In one embodiment, the electric field generation unit 107 may generate an annular electric field zone 105 about a reticle protection area surrounding reticle 104, but within the UV light curtain 102.

A simplified EUVL lithography system near the reticle 104 is shown in FIG. 1A, in accordance with an embodiment of the present invention. The EUVL system includes a vacuum chamber having a first region 122 and a second region 124 separated by barrier 112. In one embodiment, the first region 122 generally houses the reticle stage 101 that supports the reticle chuck 126 suitable for securing the reticle 104. In a further embodiment, the second region 124 generally contains the projection optics (not shown in FIG. 1A). In addition, in some instances, the second region 124 may contain a wafer stage (not shown in FIG. 1A). For example, in cases where the system 100 is adapted to control particles in a printing lithographic tool, the second region 124 may include a wafer stage. The barrier 112 that acts to generally separate the first region 122 and the second region 124 includes an aperture 113, suitable for allowing EUV light to and from the reticle.

In one embodiment, the light curtain generation unit 114 includes one or more ultraviolet light sources 116. In another embodiment, the light curtain generation unit 114 includes one or more optical elements 118 configured to form a curtain of ultraviolet light 102 by directing light from the one or more ultraviolet light sources 116 into a region, or “zone,” about the reticle protection area 106 surrounding the reticle 104, as shown in FIG. 1A.

In one embodiment, the UV light utilized to form the curtain of UV light 102 has an energy above the work function of at least some of the particles traversing through and illuminated by the curtain of UV light. In another embodiment, the UV light generated to form the curtain of UV light 102 has an energy below the ionization threshold of the material of the particles. For example, it may be desirable to utilize UV light below the ionization threshold of the material of the particles in order to avoid ionization within the particles, which may lead to unknown or uncontrollable charging phenomena. Further, the UV light generated to form the curtain of UV light 102 may have an energy above the work function of the particles traversing the curtain of UV light 102, but below the ionization energy of the particles traversing the curtain of UV light 102.

The UV light source 116 of the light curtain generation unit 114 may include any UV light source known in the art. In one embodiment, the light source 116 may include a narrow band source configured to generate UV light at one or more selected bands within the UV spectral region. For example, the light source 116 may include one or more excimer lamps (e.g., 172 nm excimer lamp). By way of another example, the light source 116 may include one or more laser sources suitable for emitting ultraviolet light. In another embodiment, the light source 116 may include a broadband source configured to generate UV light at one or more selected bands within the UV spectral region. For example, the light source 116 may include one or more broadband lamps suitable for emitting ultraviolet light. For instance, the broadband lamp may include, but is not limited to, a mercury lamp. It is noted herein that a mercury lamp may display multiple strong emission UV wavelengths, such as 165 nm, 185 nm, 194 nm, 253.6 nm, 365 nm and 400 nm. In another instance, the broadband UV lamp may include, but is not limited to, a Hg—Xe lamp, a Xe lamp, a Kr lamp, an Argon lamp or combinations thereof. In yet another instance, the broadband UV lamp may include a laser produced plasma (LPP) source or laser-sustained plasma source. It is further noted herein that the spectra emitted by a given broadband lamp may be tuned by the implemented gas type or pressure of the lamp. In some embodiments, the broadband lamp suitable for emitting ultraviolet light may include, but is not limited to, a DC lamp, a pulsed AC lamp, or an RF lamp. In a further embodiment, the light source 116 of the present invention may include any combination of the various light sources described herein.

The one or more optical elements 118 of the UV curtain generation unit 114 of the system 100 may include any optical element known in the art. In this regard, those skilled in the art will recognize that numerous optical elements and configurations may be implemented to direct UV light from the UV light source 116 onto region or zone (e.g., annular zone) surrounding the reticle protection area 106 about the reticle 104. For example, the one or more optical elements 116 may include, but are not limited to, one or more optical fibers, one or more lenses (e.g., cylindrical lens), one or more mirrors, one or more beam splitters, one or more filters and the like.

In one embodiment of the present invention, one or more optical fibers (not shown) maybe used to route UV light (190-400 nm) from the UV source 116 to one or more cylindrical glass lenses (not shown) configured to form a UV light curtain 102 about the reticle protection area 106 about the reticle 104. In this regard, the light curtain formed by the one or more cylindrical lenses may be of fixed location relative to the reticle stage 101 carrying the reticle 104. Those skilled in the art will recognize that, due to the difficulty of optical fibers to transmit UV light below 190 nm, the UV light of the UV light curtain 102 of this embodiment will include UV wavelengths in the range of approximately 190-400 nm.

In another embodiment of the present invention, UV light (e.g., 165-400 nm) is generated by multiple light sources on the outside of the vacuum chamber of the lithography system at multiple locations. It is noted herein that a laser-produced or laser-sustain plasma light source is suitable for generating light in the 165-400 nm regime. The light sources 116 then flood the stage volume (i.e., volume near the vicinity of reticle stage 101 with a uniform UV light field that is substantially perpendicular to the stage 101. In this regard, the reticle stage 101 may act to create a shadow in this flooding UV light field. In turn, the shadowing effect caused by the reticle stage 101 acts to form an annular UV light curtain 102 about the reticle protection area 106 near the reticle stage 101, as shown in FIG. 1A. It is noted herein that in this scenario the positioning of the UV light curtain 102 is generally defined by the geometry and size of the reticle stage 101.

In another embodiment of the present invention, UV light (165-400 nm) is generated and collimated on the outside of the vacuum chamber of the lithography system. Then, the UV light passes through a cylindrical or other shaped lens and immediately passes through a vacuum window. Further, the curtain of light 102 may then be steered to track the reticle stage 104 as the reticle stage 104 moves in X- and Y-directions, thereby creating a moving curtain of UV light 102 (e.g., annular curtain of UV light) around the reticle stage 101.

In one embodiment, the electric field generation unit 107 includes a first charging element 108 (e.g., charged plate) holding a first charge and a second charge element 110 holding a second charge, the first charge and second charge having opposite signs. For example, a voltage source 120 may be electrically coupled to the first charging element 108 and the second charging element 110 and suitable for biasing the first charging element 108 and the second charging element 110 such that the first charging element 108 has a negative charge, while the second charge element has a positive charge 110 (or vice-versa). In this regard, the voltage bias applied to the first charge element and the second charge element act to establish a net electric field 103 that extends (e.g., extends laterally in FIG. 1A) across a spatial zone 105 positioned between the UV light curtain 102 and the reticle protection volume 106 surrounding the reticle 104. In one embodiment, one or both of the first charge element and the second charge element may include a metal charging plate, as shown in FIG. 1A. In one embodiment, one or both of the first charging element 108 and the second charging element 110 may include a dedicated charging plate. In another embodiment, one or more of the first charging element or the second charging element may include a metal plate arranged about the reticle protection volume 106 of the reticle 104. It is noted herein that the first charging plate 108 and the second charging plate 110 may take on a number of geometrical forms. In one embodiment, the first charging plate 108 may include an annular bias plate, as depicted in FIG. 1C, suitable for surrounding the reticle protection area 106 about the reticle 104. In this regard, the annular bias plate 108 may be positioned concentrically between the external edge of the reticle protection area 106 and the internal edge of the UV light curtain 102, as shown in FIG. 1A. In a further embodiment, the second charging plate 110 may also include an annular bias plate, with the center of the second charging plate 110 being substantially aligned with the center of the first charging plate 108. It is noted herein that the first charging plate 108 and the second charging plate 110 may take on any geometric shape known in the art.

In another embodiment, one or both of the first charging element and the second charging element may include a preexisting metal component of the lithography system, such as, but not limited to, a portion of the positioning interferometer of the lithography system (see FIG. 2B) or a portion of the reticle stage of the lithography system. It is noted herein that the above description of the charging elements is not limiting and it is recognized that any number of metal components with a given lithography tool may be utilized as one or both of the first charging element or the second charging element of the system 100.

In a further embodiment, the second charging element 110 may consist of a thermophoretic plate suitable for aiding in removing particles from the reticle protection area 106 by the process of thermophoresis. In this regard, the second charging element 110 may serve a dual purpose by providing particle control via thermophoresis and by serving as a metal charging plate in the electric field generation unit 107, as described previously herein. In an alternative embodiment, the system 100 of the present invention may include an independent thermophoretic plate which acts to provide particle control in conjunction with the UV light curtain 102 and electric field generation unit 107. Thermophoresis is described generally and configurations for implementing thermophoresis based control in a EUV lithography setting are described specifically in U.S. Pat. No. 7,030,959, issued on Apr. 18, 2006; and U.S. Pat. No. 7,875,864, issued on Jan. 25, 2011, which are incorporated herein by reference in their entirety.

While the description provided throughout the present disclosure has focused on particle control near a reticle of a EUV lithography tool or EUV reticle inspection tool, it is noted herein that the present invention should be interpreted to apply to any critical region of an EUV optical tool sensitive to the presences of particles. For example, the UV light generation unit 114 and the electric field generation unit 107 of the system 100 may be extended to produce an UV light curtain 102 and an electric field zone 105 around any EUV critical region or critical zone. In one embodiment, the system 100 may generate an UV light curtain 102 and electric field zone 105 about a particle sensitive region of a sensor of an EUV reticle inspection tool. In another embodiment, the system 100 may generate an UV light curtain 102 and electric field zone 105 about a particle sensitive region of a wafer of an EUV lithography tool. In another embodiment, the system 100 may generate an UV light curtain 102 and electric field zone 105 near one or more surfaces of one or more optical elements (e.g., mirror) of an EUV reticle inspection tool or an EUV lithography tool.

FIGS. 2A and 2B illustrate schematic views of a system 200 for particle control in an actinic EUV reticle inspection tool, in accordance with embodiments of the present invention. It is noted herein that the description throughout the present disclosure with respect to the various embodiments of the present invention should be interpreted to apply to system 200 unless otherwise noted. In a general sense, the EUV reticle inspection tool includes a set of EUV capable optics 202 suitable for directing EUV light to the reticle 104. In this regard, the set of EUV optics 202 directs EUV light through barrier 112 to reticle 104. As shown in FIG. 2A, the curtain of UV light 102 may be generated by system 200 in a manner described previously herein, providing a zone (e.g., annular zone) of UV light 102 that surrounds the reticle 104 mounted on the reticle stage 101 of the EUV reticle inspection tool.

As noted previously herein, the first or second charging elements used to generate the electric field zone of the present invention may include dedicated charging elements or metallic components of the implementing EUV optical system. For example, as shown in FIG. 2A, the electric field generated by system 200 may be formed utilizing a first charging plate 208 and the thermophoretic plate 206 of the EUV reticle inspection tool. The electric field generated between dedicated plate 208 and the thermophoretic plate 206 using an applied voltage source (not shown in FIG. 2A) acts to generate an electric field extending across an electric field zone located between the reticle 104 and the generated UV light curtain 102.

By way of another example, as shown in FIG. 2B, the second charging element may include a portion of the stage interferometer mirror 214 of the EUV inspection tool. The electric field generated between dedicated plate 208 and the charged stage interferometer mirror 214 of the EUV inspection tool using an applied voltage source (not shown in FIG. 2B) acts to generate an electric field extending across an electric field zone located between the reticle 104 and the generated UV light curtain 102. It is noted herein that any metal portion of the EUV inspection tool may serve one of the charging elements used to generate the electric field of the present invention and the examples provided above should not be interpreted as limiting.

Further, it is noted that additional particle control or capture techniques may be used in concert with the UV light curtain/Electric Field approach described throughout the present disclosure. For example, the system 200 may be equipped with gas curtain capabilities used to fluidically control particles near the reticle 104. For instance, the system 200 may include a gas supply 210, which acts to supply a clean selected gas to assembly 204 of the EUV system. The supplied gas acts to “move” particles in the vicinity of the reticle 104 to positions away from the reticle via the gas exhaust 210. Particle control via a gas curtain and/or thermophoresis is described generally in U.S. Pat. No. 7,030,959, incorporated previously herein by reference in the entirety.

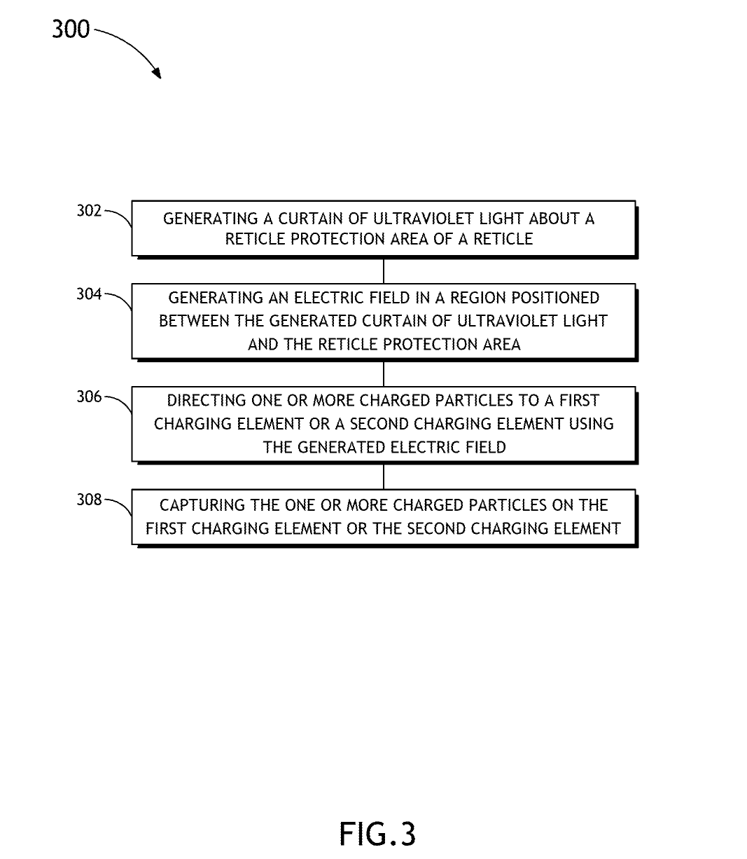

FIG. 3 illustrates a process flow diagram 300 depicting a method for controlling particles near a reticle, in accordance with an embodiment of the present invention. It is noted herein that the process 300 may be carried out in all or in part using systems 100 or 200 described previously. However, it is further noted that process 300 is not limited to the embodiments and configurations of systems 100 and 200 as other configurations and architectures may be implemented to carry out process 300.

In step 302, a curtain of ultraviolet light is generated about a reticle protection area 106 about a reticle 104. For example, a curtain of ultraviolet light 102 may be generated by illuminating a region (e.g., annular region) surrounding the reticle protection area 106 with ultraviolet light 102 having sufficient energy to induce a charge on one or more particles traversing the curtain of ultraviolet light 102. In step 304, an electric field 103 may be generated in a region 105 (e.g., annular region) positioned between the generated curtain of ultraviolet light 102 and the reticle protection area 106. For example, the electric field 103 may be generated between a first charging element 108 and a second charging element 110 having an opposite charge to the first charging element.

In step 306, one or more charged particles may be directed to a first charging element or a second charging element using the generated electric field 103. In this regard, a particle having a positive charge induced by the UV light curtain 102 will generally follow the electric field lines established between the first charging plate 108 and the second charging plate 110. In step 308, the one or more charged particles may be captured on the first charged element 108 or the second charged element 110. In this regard, in the case of a positive charge, the positively charge particle will travel toward the negatively charged charging element (108 or 110) until the positively charged particle is captured by the negatively charged charging element.

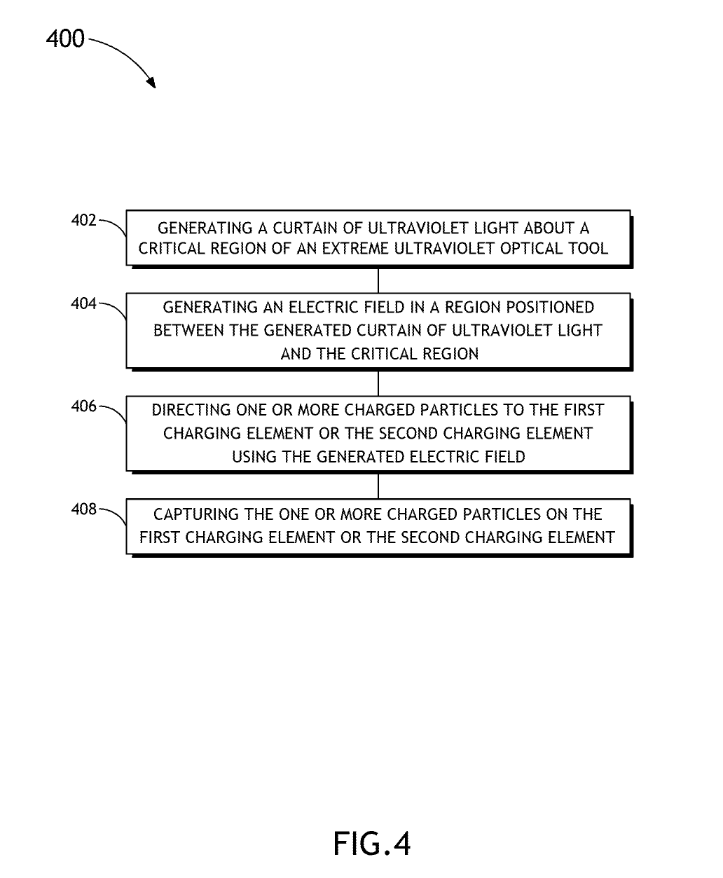

FIG. 4 illustrates a process flow diagram 400 depicting a method for controlling particles near a critical region of an EUV optical tool, in accordance with an embodiment of the present invention. It is noted herein that the process 400 may be carried out in all or in part using systems 100 or 200 described previously. However, it is further noted that process 400 is not limited to the embodiments and configurations of systems 100 and 200 as other configurations and architectures may be implemented to carry out process 400.

In step 402, a curtain of ultraviolet light is generated about a critical region of an EUV optical tool. For example, a curtain of ultraviolet light 102 may be generated by illuminating a region (e.g., annular region) surrounding a critical region (e.g., reticle protection area, sensor area, wafer area, area near optical element and the like) of an EUV optical tool (e.g., reticle inspection tool or lithography tool) with ultraviolet light 102 having sufficient energy to induce a charge on one or more particles traversing the curtain of ultraviolet light 102. In step 404, an electric field 103 may be generated in a region 105 (e.g., annular region) positioned between the generated curtain of ultraviolet light 102 and the critical region. For example, the electric field 103 may be generated between a first charging element 108 and a second charging element 110 having an opposite charge to the first charging element.

In step 406, one or more charged particles may be directed to a first charging element or a second charging element using the generated electric field 103. In this regard, a particle having a positive charge induced by the UV light curtain 102 will generally follow the electric field lines established between the first charging plate 108 and the second charging plate 110. In step 308, the one or more charged particles may be captured on the first charging element 108 or the second charging element 110. In this regard, in the case of a positive charge, the positively charge particle will travel toward the negatively charged charging element (108 or 110) until the positively charged particle is captured by the negatively charged charging element.

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

1. An apparatus for particle control near a reticle of a lithography tool or a reticle inspection tool comprising:
a curtain generation unit configured to generate a curtain of ultraviolet light about a reticle protection area surrounding a reticle by directing ultraviolet light to a selected region about the reticle protection area, the ultraviolet light having sufficient energy to induce a charge on one or more particles traversing the curtain of ultraviolet light; and
an electric field generation unit configured to generate an electric field spanning a region positioned between the curtain of ultraviolet light and the reticle protection area.

2. The apparatus of claim 1, wherein the curtain generation unit comprises:
an ultraviolet light source configured to generate ultraviolet light;
one or more optical elements configured to form a curtain of ultraviolet light about a reticle protection area surrounding the reticle by directing the ultraviolet from the ultraviolet light source to a selected region about the reticle protection area.

3. The apparatus of claim 2, wherein the ultraviolet light source comprises:
one or more broadband light sources.

4. The apparatus of claim 2, wherein the ultraviolet light source comprises:
one or more narrowband light sources.

5. The apparatus of claim 2, wherein the one or more optical elements comprises:
one or more optical fibers.

6. The apparatus of claim 2, wherein the one or more optical elements comprise:
one or more lenses having a selected shape.

7. The apparatus of claim 6, wherein the one or more lenses having a selected shape comprise:
one or more cylindrical lenses.

8. The apparatus of claim 1, wherein the selected region comprises:
an annular region about the reticle protection area.

9. The apparatus of claim 1, wherein the ultraviolet light of the curtain ultraviolet light comprises:
ultraviolet light having an energy level larger than the work function associated with the one or more particles.

10. The apparatus of claim 1, wherein the ultraviolet light of the curtain ultraviolet light comprises:
ultraviolet light having an energy level below the ionization threshold associated with the one or more particles.

11. The apparatus of claim 1, wherein the electric field generation unit comprises:
a first charge element;
a second charge element;
a voltage source coupled to the first charge element and the second charge element and configured to induce a first charge on the first charge element and a second charge on the second charge element, the second charge element having an opposite polarity to the first charge element.

12. The apparatus of claim 11, wherein at least one of the first charging element and the second charging element comprise:
a metal charging plate.

13. The apparatus of claim 11, wherein at least one of the first charging element and the second charging element comprise:
a metal portion of the lithography tool or reticle inspection tool.

14. An apparatus for particle control near a reticle of a lithography tool or reticle inspection tool comprising:
a curtain generation unit configured to generate a curtain of ultraviolet light about a reticle protection area surrounding a reticle by directing ultraviolet light to a selected region about the reticle protection area, the ultraviolet light having sufficient energy to induce a charge on one or more particles traversing the curtain of ultraviolet light;
a thermophoretic plate arranged near a surface of the reticle and suitable for directing one or more particles away from the reticle protection area about the reticle via the thermophoretic effect; and
an electric field generation unit configured to generate an electric field spanning a region positioned between the curtain of ultraviolet light and the reticle protection area, wherein the electric field generation unit is configured to charge the thermophoretic plate and charge a second charging element, wherein the thermophoretic plate and the second charging element have opposite polarity.

15. The apparatus of claim 14, wherein the curtain generation unit comprises:
an ultraviolet light source configured to generate ultraviolet light;
one or more optical elements configured to form a curtain of ultraviolet light about a reticle protection area surrounding the reticle by directing the ultraviolet from the ultraviolet light source to a selected region about the reticle protection area.

16. The apparatus of claim 15, wherein the ultraviolet light source comprises:
one or more broadband light sources.

17. The apparatus of claim 15, wherein the ultraviolet light source comprises:
one or more narrowband light sources.

18. The apparatus of claim 15, wherein the one or more optical elements comprises:
one or more optical fibers.

19. The apparatus of claim 15, wherein the one or more optical elements comprise:
one or more lenses having a selected shape.

20. The apparatus of claim 19, wherein the one or more lenses having a selected shape comprise:
one or more cylindrical lenses.

21. The apparatus of claim 14, wherein the selected region comprises:
an annular region about the reticle protection area.

22. The apparatus of claim 14, wherein the ultraviolet light of the curtain ultraviolet light comprises:
ultraviolet light having an energy level larger than the work function associated with the one or more particles.

23. The apparatus of claim 14, wherein the ultraviolet light of the curtain ultraviolet light comprises:
ultraviolet light having an energy level below the ionization threshold associated with the one or more particles.

24. The apparatus of claim 14, wherein the electric field generation unit comprises:
a voltage source coupled to the thermophoretic plate and the second charging element and configured to induce a first charge on the thermophoretic plate and a second charge on the second charging element, the second charging element having an opposite polarity to the thermophoretic plate.

25. The apparatus of claim 14, wherein the second charging element comprises:
a metal charging plate.

26. The apparatus of claim 14, wherein the second charging element comprises:
a metal portion of the lithography or reticle inspection tool.

27. An apparatus for controlling particles near a critical region of an extreme ultraviolet optical tool comprising:
a curtain generation unit configured to generate a curtain of ultraviolet light about a critical region of an extreme ultraviolet light optical tool by directing ultraviolet light to a selected region about the critical region, the ultraviolet light having sufficient energy to induce a charge on one or more particles traversing the curtain of ultraviolet light; and
an electric field generation unit configured to generate an electric field spanning a region positioned between the curtain of ultraviolet light and the critical region.

28. The apparatus of claim 27, wherein the curtain generation unit comprises:
an ultraviolet light source configured to generate ultraviolet light;
one or more optical elements configured to form a curtain of ultraviolet light about a critical region of an extreme ultraviolet light optical tool by directing the ultraviolet from the ultraviolet light source to a selected region about the critical region.

29. The apparatus of claim 28, wherein the ultraviolet light source comprises:
one or more broadband light sources.

30. The apparatus of claim 28, wherein the ultraviolet light source comprises:
one or more narrowband light sources.

31. The apparatus of claim 28, wherein the one or more optical elements comprise:
one or more optical fibers.

32. The apparatus of claim 28, wherein the one or more optical elements comprise:
one or more lenses having a selected shape.

33. The apparatus of claim 32, wherein the one or more lenses having a selected shape comprise:
one or more cylindrical lenses.

34. The apparatus of claim 28, wherein the selected region comprises:
an annular region about the critical region.

35. The apparatus of claim 28, wherein the ultraviolet light of the curtain ultraviolet light comprises:
ultraviolet light having an energy level larger than the work function associated with the one or more particles.

36. The apparatus of claim 28, wherein the ultraviolet light of the curtain ultraviolet light comprises:
ultraviolet light having an energy level below the ionization threshold associated with the one or more particles.

37. The apparatus of claim 28, wherein the electric field generation unit comprises:
a first charge element;
a second charge element;
a voltage source coupled to the first charge element and the second charge element and configured to induce a first charge on the first charge element and a second charge on the second charge element, the second charge element having an opposite polarity to the first charge element.

38. The apparatus of claim 37, wherein at least one of the first charging element and the second charging element comprise:
a metal charging plate.

39. The apparatus of claim 37, wherein at least one of the first charging element and the second charging element comprise:
a metal portion of the extreme ultraviolet light optical tool.

40. The apparatus of claim 28, wherein the extreme ultraviolet light optical tool comprises:
at least one of an extreme ultraviolet lithography tool and an extreme ultraviolet reticle inspection tool.

41. The apparatus of claim 28, wherein the critical region of an extreme ultraviolet optical tool comprises:
a reticle protection area of an extreme ultraviolet lithography tool and an extreme ultraviolet reticle inspection tool.

42. The apparatus of claim 28, wherein the critical region of an extreme ultraviolet optical tool comprises:
a sensor area of an extreme ultraviolet reticle inspection tool.

43. The apparatus of claim 28, wherein the critical region of an extreme ultraviolet optical tool comprises:
a wafer area of an extreme ultraviolet lithography tool.

44. The apparatus of claim 28, wherein the critical region of an extreme ultraviolet optical tool comprises:
an area near one or more surfaces of one or more optical elements of at least one of sensor area of an extreme ultraviolet lithography tool and an extreme ultraviolet reticle inspection tool.

45. A method for controlling particles near a reticle comprising:
generating a curtain of ultraviolet light about a reticle protection area of a reticle by illuminating a region surrounding the reticle protection area with ultraviolet light having sufficient energy to induce a charge on one or more particles traversing the curtain of ultraviolet light;
generating an electric field in a region positioned between the generated curtain of ultraviolet light and the reticle protection area, the electric field generated between a first charging element and a second charging element having an opposite charge to the first charging element;
directing one or more charged particles to the first charging element or the second charging element using the generated electric field; and
capturing the one or more charged particles on the first charging element or the second charging element.

46. The method of claim 45, wherein the generating a curtain of ultraviolet light about a reticle protection area of a reticle by illuminating a region surrounding the reticle protection area with ultraviolet light comprises:
generating a curtain of ultraviolet light about a reticle protection area of a reticle by illuminating an annular shaped region surrounding the reticle protection area with ultraviolet light.

47. The method of claim 45, wherein at least one of the first charging element and the second charging element comprises:
an annular shaped charging plate.

48. A method for controlling particles near a critical region of an extreme ultraviolet optical tool comprising:
generating a curtain of ultraviolet light about a critical region of an extreme ultraviolet optical tool by illuminating a region surrounding the critical region with ultraviolet light having sufficient energy to induce a charge on one or more particles traversing the curtain of ultraviolet light;
generating an electric field in a region positioned between the generated curtain of ultraviolet light and the critical region, the electric field generated between a first charging element and a second charging element having an opposite charge to the first charging element;
directing one or more charged particles to the first charging element or the second charging element using the generated electric field; and
capturing the one or more charged particles on the first charging element or the second charging element.

49. The method of claim 48, wherein the generating a curtain of ultraviolet light about a critical region of an extreme ultraviolet optical tool by illuminating a region surrounding the critical region with ultraviolet light comprises:
generating a curtain of ultraviolet light about a critical region of an extreme ultraviolet optical tool by illuminating an annular shaped region surrounding critical region with ultraviolet light.

50. The method of claim 48, wherein at least one of the first charging element and the second charging element comprises:
an annular shaped charging plate.
